(19) United States
(12) Patent Application Publication
(10) Pub. No.: US 2026/0206292 A1
(43) Pub. Date: Jul. 16, 2026

(54) STACKED MULTI-GATE DEVICES

(71) Applicant: Taiwan Semiconductor Manufacturing Company, Ltd., Hsin-Chu (TW)

(72) Inventors: Chih-Pin Lin, Hsinchu (TW); Zhi-Chang Lin, Hsinchu County (TW)

(21) Appl. No.: 19/016,386

(22) Filed: Jan. 10, 2025

(51) Int. Cl. H10D 84/01; H01L 21/02; H10D 30/00; H10D 30/01; H10D 30/43; H10D 62/00; H10D 62/10; H10D 62/832; H10D 64/01; H10D 84/85

(52) U.S. Cl. CPC H10D 84/0188; H10D 30/014; H10D 30/0191; H10D 30/43; H10D 30/501; H10D 62/021; H10D 62/121; H10D 62/832; H10D 64/017; H10D 84/0167; H10D 84/017; H10D 84/0172; H10D 84/851; H10P 14/6339; H10P 14/6939; H10P 14/69391

(57) ABSTRACT

Semiconductor devices and methods of forming the same are provided. An exemplary method includes forming a superlattice structure over a substrate, the superlattice structure comprising an upper portion separated from a lower portion by an insulation layer, wherein the insulation layer comprises a crystalline metal oxide, patterning the superlattice structure to form a fin protruding from the substrate, forming a dummy gate stack over a first portion of the fin, recessing a second portion of the fin not covered by the dummy gate stack to form a source/drain trench, forming a first source/drain feature in the source/drain trench and coupled to the lower portion of the superlattice structure, forming a second source/drain feature in the source/drain trench and coupled to the upper portion of the superlattice, and replacing the dummy gate stack by a gate structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FETs) where an n-type multi-gate transistor and a p-type multi-gate transistor are stacked vertically, one over the other. While existing methods for forming C-FETs are generally adequate, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a perspective view of a semiconductor device including a vertical C-FET, according to one or more aspects of the present disclosure.

FIG. 2 illustrates a flow chart of a method for forming the semiconductor device, according to one or more aspects of the present disclosure.

FIGS. 3, 4, 5, 6, 7, 8, 9 illustrate fragmentary cross-sectional views of the semiconductor device during various fabrication stages in the method of FIG. 2, according to various aspects of the present disclosure.

FIGS. 10, 11, 12 illustrate fragmentary cross-sectional views of alternative semiconductor devices, according to one or more aspects of the present disclosure.

FIG. 13 illustrates a flow chart of a method for forming a semiconductor device including a GAA transistor, according to one or more aspects of the present disclosure.

FIGS. 14, 15, 16, 17, 18, 19 illustrate fragmentary cross-sectional views of the semiconductor device during various fabrication stages in the method of FIG. 13, according to various aspects of the present disclosure.

FIGS. 20, 21, 22, 23 illustrate fragmentary cross-sectional views of another semiconductor device during various fabrication stages in the method of FIG. 2, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A stacked multi-gate device refers to a semiconductor device that includes a bottom multi-gate device and a top multi-gate device stacked over the bottom multi-gate device. When the bottom multi-gate device and the top multi-gate device are of different conductivity types, the stacked multi-gate device may be a complementary field effect transistor (C-FET). The multi-gate devices in a C-FET may be FinFETs or GAA transistors. In some fabrication processes for forming C-FET devices, a superlattice structure for forming the C-FET devices includes a top portion formed of a number of first channel layers interleaved by a number of first sacrificial layers, a bottom portion formed of a number of second channel layers interleaved by a number of second sacrificial layers, and a middle portion between the top portion and the bottom portion and including a third sacrificial layer. The third sacrificial layer will be replaced by a dielectric layer to provide isolation between gate structure of the top multi-gate device and gate structure of the bottom multi-gate device. During subsequent processes, an etching process is performed to recess first and second sacrificial layers to form inner spacer recesses. The etching process may also be configured to remove the third sacrificial layer to facilitate the formation of the dielectric layer. However, the extent at which the third sacrificial layer being removed is dependent on the gate length of the dummy gate stack thereover. For embodiments in which semiconductor device includes dummy gate stacks with different gate lengths, upon completion of the etching process for forming the inner spacer recesses, the part of the third sacrificial layer under the dummy gate stack having a large gate length may not be fully removed, leaving a residue (e.g., SiGe) disposed vertically between the first and second channel layers. If left untreated, the residue may provide a current path between the gate structure of the top multi-gate device and the gate structure of the bottom multi-gate device and thus disadvantageously affect the performance and reliability of the C-FET devices.

The present disclosure provides a method of forming C-FET devices with improved performance and reliability. A superlattice structure of this present disclosure includes a top portion formed of a number of first channel layers interleaved by a number of first sacrificial layers, a bottom portion formed of a number of second channel layers interleaved by a number of second sacrificial layers, and a middle portion between the top portion and the bottom portion and including a dielectric layer. In an embodiment, the dielectric layer includes crystalline metal oxide. During subsequent processes, the etching process for forming the inner spacer recesses will not substantially etch the dielectric layer. Thus, effect of gate lengths of dummy gate stacks on the etching result of the etching process may be mitigated. The dummy gate stacks are then replaced by gate structures. The dielectric layer will provide isolation between gate structure of the top multi-gate device and gate structure of the bottom multi-gate device. By forming the dielectric layer during the formation of the superlattice structure, electrical isolation between gate structure of the top multi-gate device and gate structure of the bottom multi-gate device is advantageously enhanced, and reliability of the stacked multi-gate device is improved.

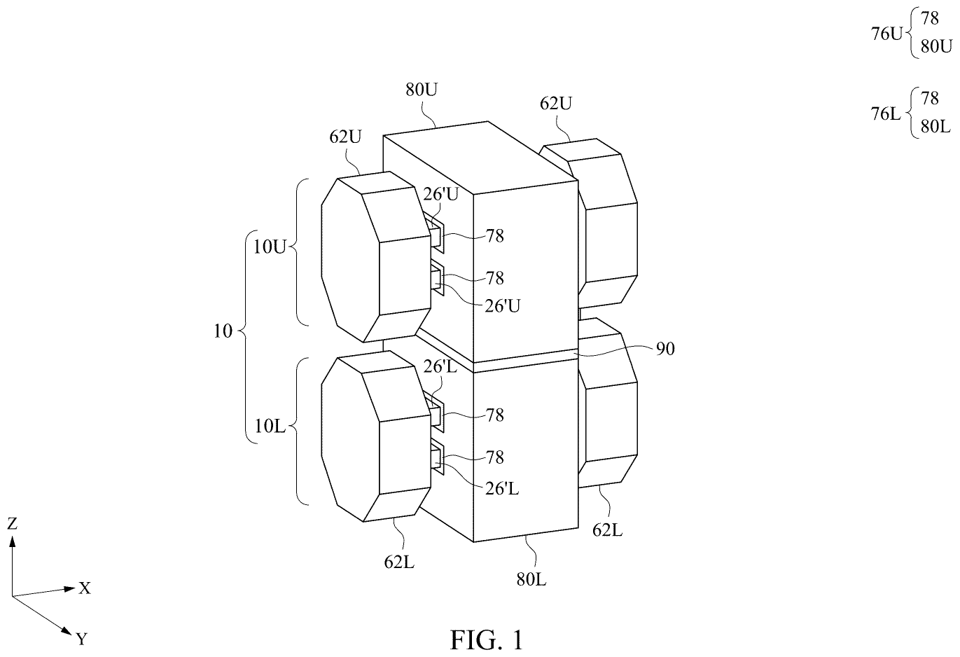

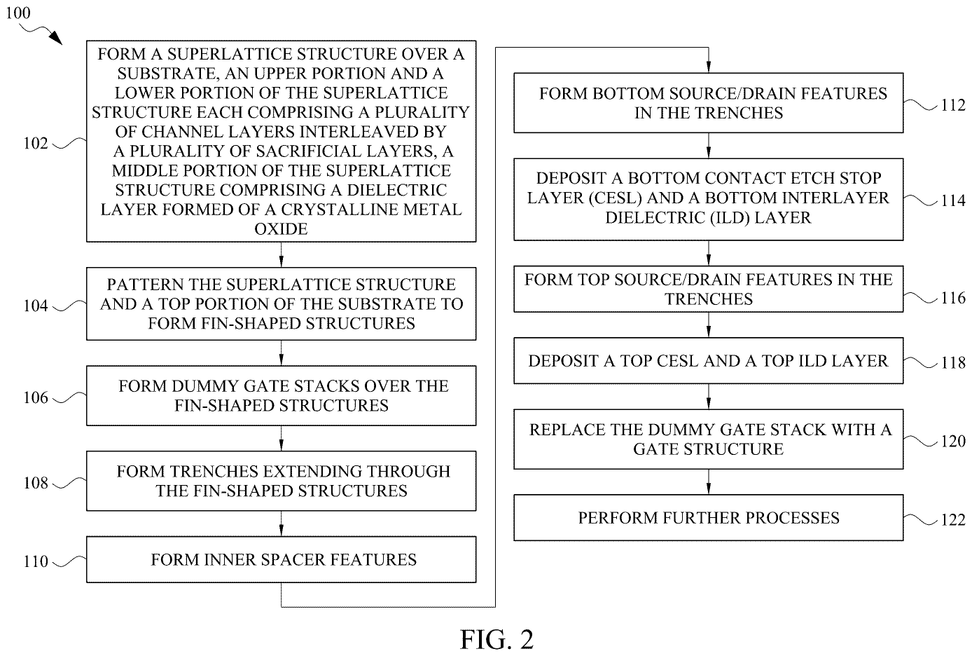

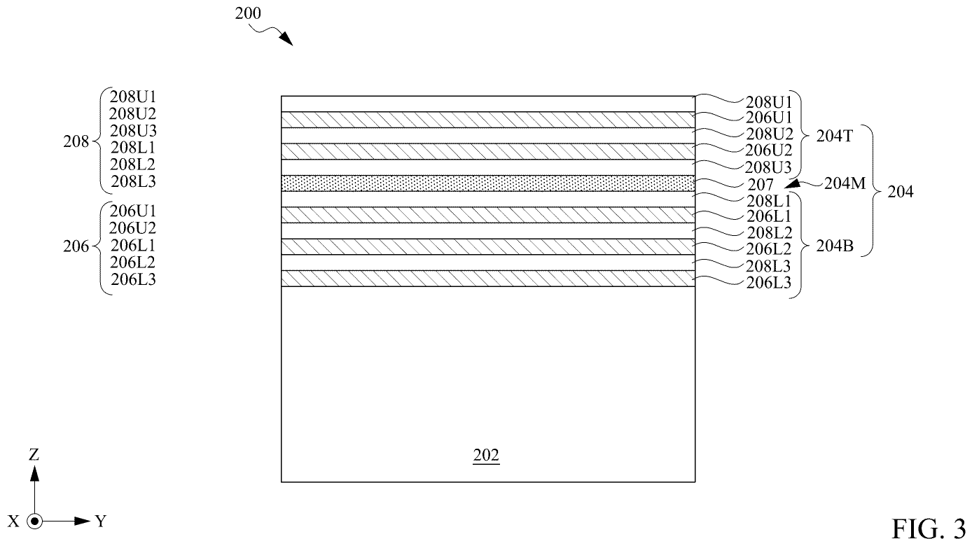

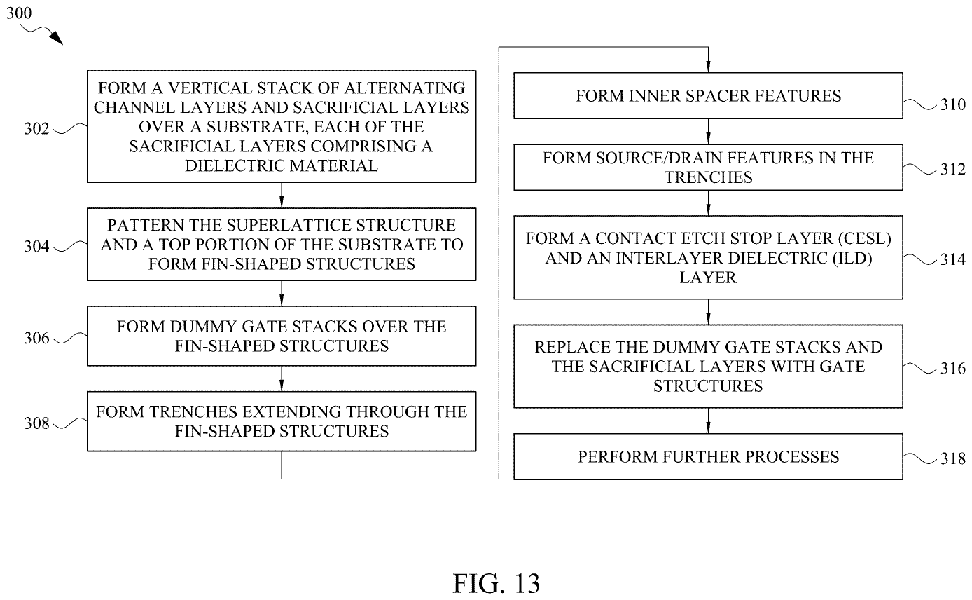

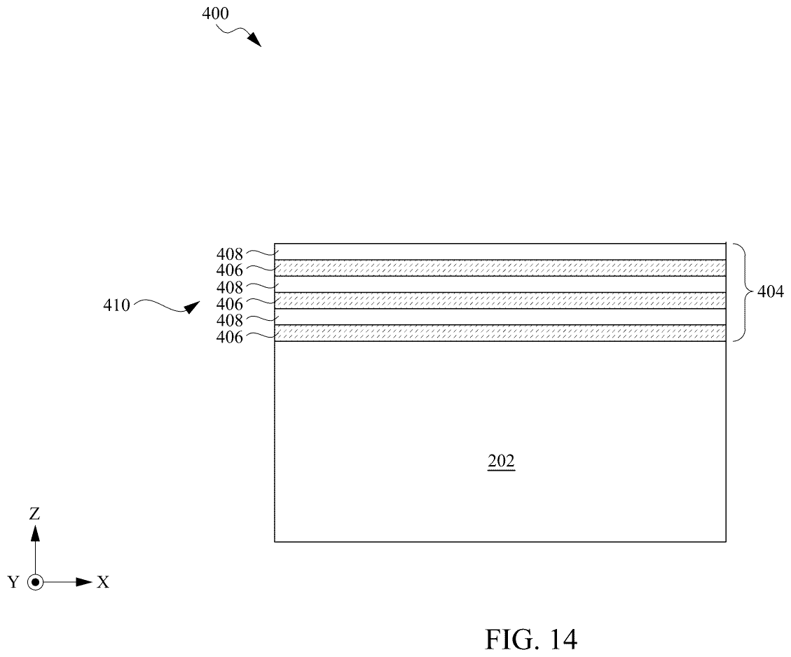

The various aspects of the present disclosure will now be described in more detail with reference to the figures. In that regard, FIG. 1 illustrates a perspective view of a semiconductor device including a vertical C-FET, according to one or more aspects of the present disclosure. FIG. 2 illustrates a flow chart of a method 100 for forming a semiconductor device 200 or a semiconductor device 600 including vertical C-FETs, according to one or more aspects of the present disclosure. Method 100 is described below in conjunction with FIGS. 3A-12 and 20-23, which are fragmentary cross-sectional views of the intermediate structure at different stages of fabrication according to embodiments of method 100. FIG. 13 illustrates a flow chart of a method 300 for forming a semiconductor device 400 including GAAs, according to one or more aspects of the present disclosure. Method 300 is described below in conjunction with FIGS. 14-19, which are fragmentary cross-sectional views of the intermediate structure at different stages of fabrication according to embodiments of method 300. Method 100 and method 300 are merely examples and are not intended to limit the present disclosure to what is explicitly illustrated therein. Additional steps may be provided before, during and after method 100 and method 300, and some steps described can be replaced, eliminated, or moved around for additional embodiments of the method. Not all steps are described herein in detail for reasons of simplicity. Because the intermediate structures 200, 400, 600 will be fabricated into semiconductor devices 200, 400, 600 upon conclusion of the fabrication processes, the intermediate structures 200, 400, 600 may be referred to as the semiconductor devices 200, 400, 600 as the context requires. Additionally, throughout the present application and across different embodiments, like reference numerals denote like features with similar structures and compositions, unless otherwise excepted. For avoidance of doubts, the X, Y and Z directions in the figures are perpendicular to one another and are used consistently.

FIG. 1 depicts an exemplary semiconductor device (e.g., C-FET) 10. The semiconductor device 10 includes a lower device 10L (e.g., p-type transistor) and an upper device 10U (e.g., n-type transistor) over the lower device 10L. The lower device 10L includes channel layers 26′L wrapped around by a bottom gate structure 76L. The bottom gate structure 76L includes a gate dielectric layer 78 and a conductive structure 80L. The lower device 10L also includes source/drain features (e.g., p-type epitaxial source/drain features) 62L coupled to the channel layers 26′L and adjacent the bottom gate structure.

The upper device 10U includes channel layers 26′U wrapped around by an upper gate structure 76U. The upper gate structure 76U includes the gate dielectric layer 78 and a conductive structure 80U. The upper device 10U also includes source/drain features (e.g., n-type epitaxial source/drain features) 62U coupled to the channel layers 26′U and adjacent the upper gate structure. An isolation layer 90 is disposed between the upper device 10U and the lower device 10L to electrically insulate the upper gate structure 76U of the upper device 10U from the bottom gate structure 76L of the lower device 10L. The configurations of the elements in the semiconductor device 10 described above are given for illustrative purposes and can be modified depending on the actual implementations. It is understood that some features are omitted in this figure for reason of simplicity.

Referring now to FIGS. 2 and 3, method 100 includes a block 102 where a superlattice structure 204 is formed over a substrate 202. In one embodiment, the substrate 202 may be a silicon (Si) substrate. In some other embodiments, the substrate 202 may include other semiconductors such as germanium (Ge), silicon germanium (SiGe), or a III-V semiconductor material. Exemplary III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure. In another embodiment, the substrate 202 may include one or more epitaxial semiconductor layers embedded in a bulk semiconductor layer. The one or more epitaxial semiconductor layers and the bulk semiconductor layer may have different compositions. Although not explicitly shown in the figures, the substrate 202 may include an n-type well region and a p-type well region for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202. For ease of reference, the substrate 202 and structures formed thereon during the method 100 may be referred to as an intermediate structure 200.

The superlattice structure 204 is formed over the substrate 202. For ease of references, the superlattice structure 204 may be vertically divided into a bottom portion 204B, a middle portion 204M on the bottom portion 204B, and a top portion 204T on the middle portion 204M. In this depicted example, the bottom portion 204B of the superlattice structure 204 includes channel layers 208L1, 208L2 and 208L3 interleaved by sacrificial layers 206L1, 206L2, and 206L3. The top portion 204T of the superlattice structure 204 includes channel layers 208U1, 208U2, 208U3 interleaved by sacrificial layers 206U1 and 206U2. In some embodiments, the channel layers 208U1-208U2 will provide channel members for a top GAA transistor, and the channel layers 208L2-208L3 will provide channel members for a bottom GAA transistor in the C-FET 10, respectively. The term “channel member(s)” is used herein to designate any material portion for channel(s) in a transistor with nanoscale dimensions, and having an elongate shape, regardless of the cross-sectional shape of this portion.

The channel layers 208U1, 208U2, 208U3, 208L1, 208L2 and 208L3 may be separately or collectively referred to as channel layer(s) 208. The sacrificial layers 206U1, 206U2, 206L1, 206L2, and 206L3 may be separately or collectively referred to as sacrificial layer(s) 206. The channel layers 208 and the sacrificial layers 206 may be epitaxially deposited on the substrate 201 using molecular beam epitaxy (MBE), vapor-phase epitaxy (VPE), ultra-high vacuum CVD (UHV-CVD), and/or other suitable epitaxial growth processes. The sacrificial layers 206 and the channel layers 208 in the top portion 204T and the bottom portion 204B are deposited alternatingly, one-after-another, to form the superlattice structure 204. The channel layers 208 and the sacrificial layers 206 may have different semiconductor compositions. In some implementations, the channel layers 208 are formed of silicon (Si) and sacrificial layers 206 are formed of silicon germanium (SiGe). In these implementations, the additional germanium content in the sacrificial layers 206 allow selective removal or recess of the sacrificial layers 206 without inducing substantial damages to the channel layers 208.

It is noted that the superlattice structure 204 in FIG. 3 includes six (6) layers of the channel layers 208 interleaved by five (5) layers of sacrificial layers 206, which is for illustrative purposes only and not intended to be limiting beyond what is specifically recited in the claims. It can be appreciated that any number of the channel layers 208 can be included in the superlattice structure 204 and distributed between the bottom portion 204B and the top portion 204T. The number of layers depends on the desired number of channels members for the top GAA transistor and the bottom GAA transistor. In some embodiments, the number of the channel layers 208 in the superlattice structure 204 may be between 4 and 10. The thicknesses of the channel layers 208 and the sacrificial layers 206 may be selected based on device performance considerations of the bottom GAA transistor, the top GAA transistor, and the C-FET as a whole.

In the present embodiment, the middle portion 204M provides physical and electrical isolation between the top portion 204T and the bottom portion 204B. In an embodiment, the middle portion 204M includes a dielectric layer 207. That is, composition of the middle portion 204M is different from composition of the channel layers 208 and composition of the sacrificial layer 206. In an embodiment, an etching process may etch the channel layer 208 at a first rate, etch the dielectric layer 207 at a second rate, and etch the sacrificial layer 206 at a third rate, and the third rate is greater than the first rate and the second rate. To provide better epitaxial morphology for semiconductor layers (e.g., the channel layers 208 and sacrificial layers 206 of the top portion 204T) formed over the dielectric layer 207, the dielectric layer 207 may be formed of a crystalline metal oxide, such as beryllium oxide (BeO), aluminum oxide (Al₂O₃) or other suitable materials, and may be formed by atomic layer deposition (ALD) process, plasma-enhanced atomic layer deposition process (PEALD), or other suitable processes. The formation of the superlattice structure 204 may include performing a first epitaxial process to form the bottom portion 204B, a deposition process (e.g., ALD process) to form the dielectric layer 207 on the bottom portion 204B, and a second epitaxial process to form the top portion 204T on the dielectric layer 207. In some embodiments, the dielectric layer 207 has a thickness T1 along the Z direction. The thickness T1 may be between about 5 nm and about 15 nm. If the thickness T1 is less than about 5 nm, after going through multiple fabrication processes, the dielectric layer 207 may not be thick enough to provide satisfactory isolation between gate structure of the top GAA transistor and gate structure of the bottom GAA transistor. If the thickness T1 is greater than about 15 nm, a total thickness of the superlattice structure 204 may be too thick, increasing the difficulty of forming satisfactory deep source/drain trenches and forming bottom source/drain features and inner spacer features under the dielectric layer 207.

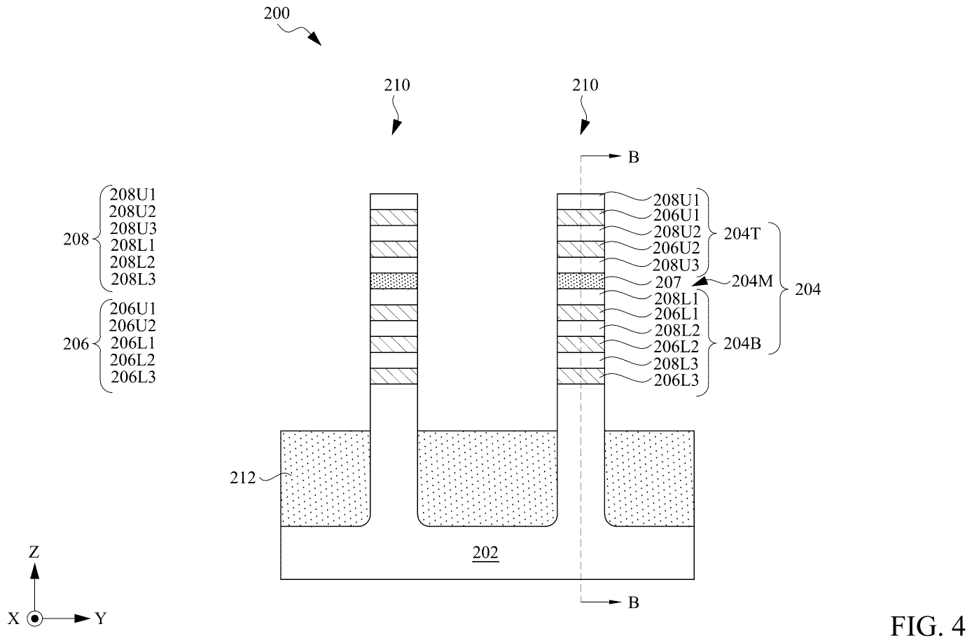

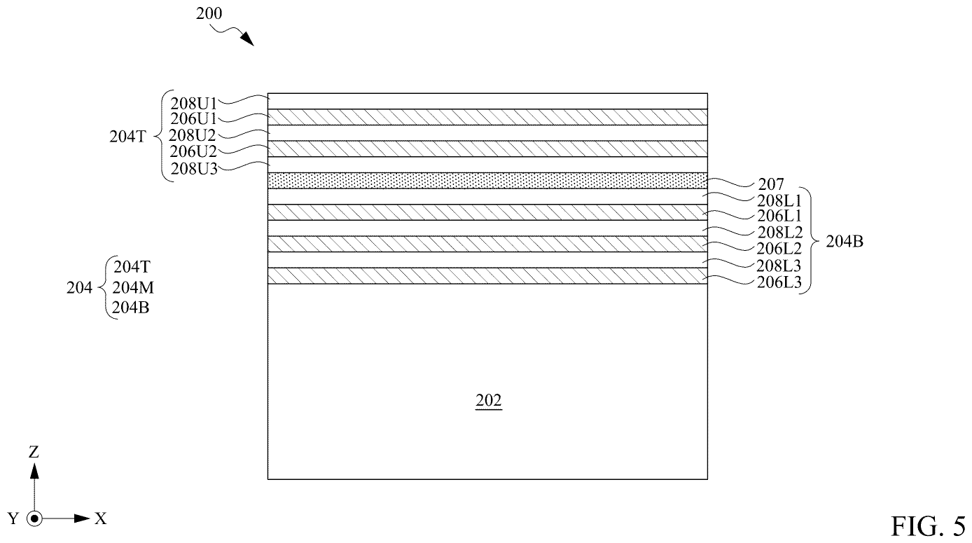

Referring now to FIGS. 2 and 4-5, method 100 includes a block 104 where the superlattice structure 204 and a portion of the substrate 202 are patterned to form fin-shaped structures 210. FIG. 4 depicts a cross-sectional view of the intermediate structure 200, and FIG. 5 depicts a cross-sectional view of the intermediate structure 200 taken along line B-B shown in FIG. 4. After forming the superlattice structure 204, the superlattice structure 204 and a top portion of the substrate 202 are then patterned to form the fin-shaped structures 210. For patterning purposes, a hard mask layer may be deposited over the superlattice structure 204. The hard mask layer may be a single layer or a multilayer. In one example, the hard mask layer includes a silicon oxide layer and a silicon nitride layer over the silicon oxide layer. As shown in FIGS. 4-5, each fin-shaped structure 210 extends vertically along the Z direction from the substrate 202 and extends lengthwise along the X direction. The fin-shaped structures 210 may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the superlattice structure 204 and the substrate 202 to form the fin-shaped structures 210.

After forming the fin-shaped structures 210, an isolation feature 212 is formed around the fin-shaped structures 210 to separate two adjacent fin-shaped structures 210. The isolation feature 212 may also be referred to as a shallow trench isolation (STI) feature 212. In an example process, a dielectric material for the isolation feature 212 is deposited over the intermediate structure 200, including the fin-shaped structure 210, using CVD, sub-atmospheric CVD (SACVD), flowable CVD, spin-on coating, and/or other suitable process. Then the deposited dielectric material is planarized and recessed to form the isolation feature 212. As shown in FIG. 4, the fin-shaped structure 210 rises above the isolation feature 212. The dielectric material for the isolation feature 212 may include silicon oxide, silicon oxynitride, fluorine-doped silicate glass (FSG), a low-k dielectric, combinations thereof, and/or other suitable materials. In an embodiment, the isolation feature 212 includes silicon oxide. The top surface of the top portion of the substrate 202 may be above the top surface of the isolation feature 212. In some embodiment, the top surface of the isolation feature 212 may be a concave surface that curves inward.

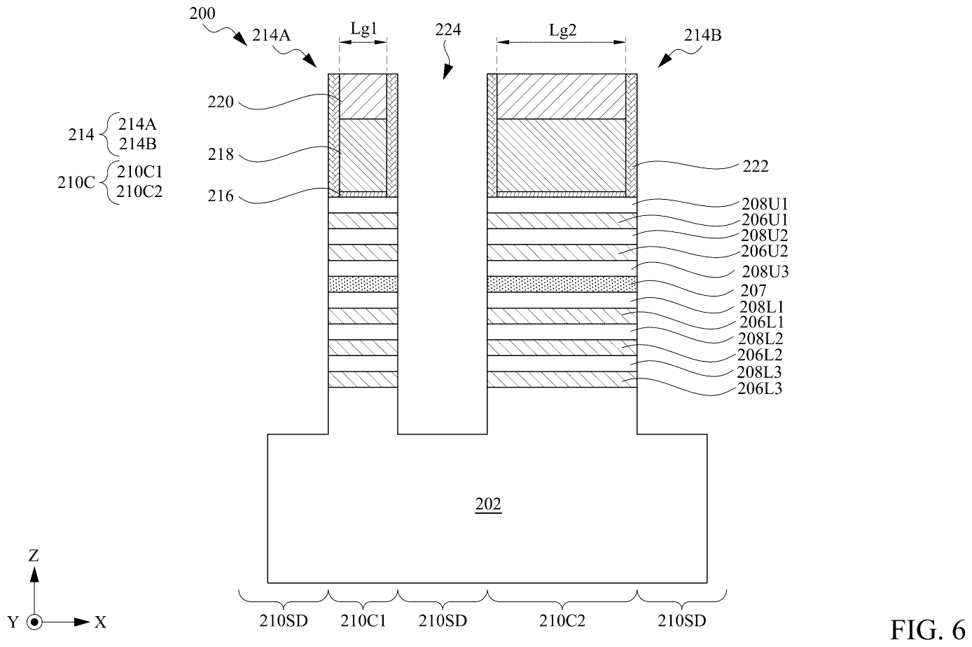

Referring to FIGS. 2 and 6, method 100 includes a block 106 where dummy gate stacks 214 are formed over channel regions 210C of the fin-shaped structure 210. In some embodiments, a gate replacement process (or gate-last process) is adopted where the dummy gate stacks 214 serve as placeholders for functional gate structures. Other processes and configurations are possible. To form the dummy gate stacks 214, a dummy dielectric layer 216, a dummy gate electrode layer 218, and a gate-top hard mask layer 220 are deposited over the intermediate structure 200. The deposition of these layers may include use of low-pressure CVD (LPCVD), CVD, plasma-enhanced CVD (PECVD), physical vapor deposition (PVD), atomic layer deposition (ALD), thermal oxidation, e-beam evaporation, other suitable deposition techniques, and/or combinations thereof. The dummy dielectric layer 216 may include silicon oxide, the dummy gate electrode layer 218 may include polysilicon, and the gate-top hard mask layer 220 may be a multi-layer that includes silicon oxide and silicon nitride. Using photolithography and etching processes, the gate-top hard mask layer 220 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching, wet etching, and/or other etching methods. Like the fin-shaped structures 210, the dummy gate stack 214 may also be patterned using double-patterning or multiple-patterning techniques. Thereafter, using the patterned gate-top hard mask 220 as an etch mask, the dummy dielectric layer 216 and the dummy gate electrode layer 218 are then etched to form the dummy gate stacks 214. The dummy gate stacks 214 each extend lengthwise along the Y direction to wrap over the fin-shaped structure 210 and land on the isolation feature 212. The portion of the fin-shaped structure 210 underlying the dummy gate stack 214 defines a channel region 210C. The channel region 210C and the dummy gate stack 214 also define source/drain regions 210SD that are not vertically overlapped by the dummy gate stack 214. The channel region 210C is disposed between two source/drain regions 210SD along the Y direction. Source/drain region(s) may refer to a source region for forming a source or a drain region for forming a drain, individually or collectively dependent upon the context. In this embodiment, the dummy gate stacks 214 may have different gate lengths along the X direction to form C-FETs with different performances. For example, a first dummy gate stack 214A of the dummy gate stacks 214 has a first gate length Lg1 and disposed directly over a first channel region 210C1, and a second dummy gate stack 214B of the dummy gate stacks 214 has a second gate length Lg2 and disposed directly over a second channel region 210C2, and the second dummy gate length Lg2 is greater than the first dummy gate length Lg1. That is, the channel length of the second channel region 210C2 is greater than the channel length of the first channel region 210C1.

Still referring to FIGS. 2 and 6, method 100 includes a block 108 where source/drain regions 210SD of the fin-shaped structure 210 are recessed to form trenches 224. Operations at block 108 may include formation of at least one gate spacer 222 over the sidewalls of the dummy gate stacks 214 before the source/drain regions 210SD are recessed. In some embodiments, the formation of the at least one gate spacer 222 includes deposition of one or more dielectric layers over the intermediate structure 200. In an example process, the one or more dielectric layers are conformally deposited using CVD, SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. After the deposition of the at least one gate spacer 222, an anisotropic etch process is performed to the intermediate structure 200 to form the trenches 224. The etch process at block 108 may be a dry etch process or other suitable etch process. As shown in FIG. 6, sidewalls of the sacrificial layers 206 and the channel layers 208 and sidewalls of the dielectric layer 207 in the channel regions 210C are exposed in the trenches 224.

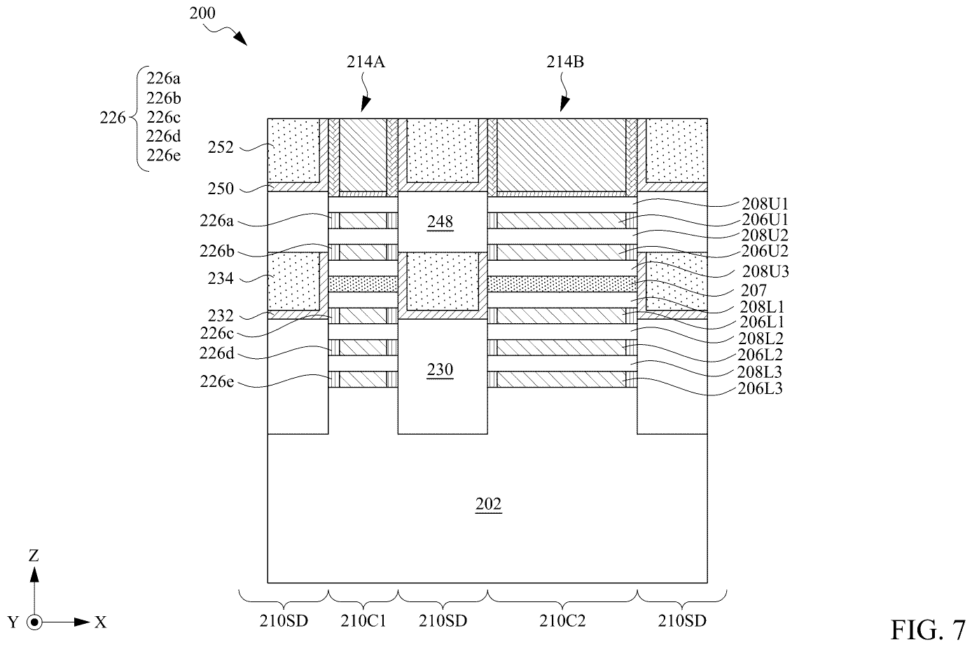

Referring to FIGS. 2 and 7, method 100 includes a block 110 where inner spacer features 226 are formed. At block 110, the sacrificial layers 206 exposed in the trenches 224 are selectively and partially recessed to form inner spacer recesses, while the exposed channel layers 208 and the dielectric layer 207 are substantially unetched. In some embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include use of hydrogen fluoride (HF) or ammonium hydroxide (NH₄OH). In an embodiment, etchant of the selective isotropic etching process etches the channel layers 208 at a first rate, etches the dielectric layer 207 at a second rate, and etches the sacrificial layers 206 at a third rate. The third rate is greater than the first rate and the second rate. For example, a ratio of the third rate to the second rate is greater than 5 such that the dielectric layer 207 will not be fully removed upon formation of the inner spacer recesses. In another embodiment, a ratio of the third rate to the second rate is greater than 20 such that the dielectric layer 207 will not be substantially etched upon formation of the inner spacer recesses.

In some existing technologies, the middle portion 204M is a sacrificial layer (or “sacrificial middle layer 204M”), such as a silicon germanium layer that has a germanium concentration higher than that of the sacrificial layer 206. During the performing of the selective isotropic etching process for forming the inner spacer recesses, ideally the sacrificial middle portion 204M (e.g., SiGe) is fully removed to release space for forming an isolation layer that will provide isolation between gate structure of the bottom GAA transistor and the gate structure of the top GAA transistor. However, the extent at which the sacrificial middle layer 204M being etched is dependent on the length of the gate length. For embodiments in which the intermediate structure 200 includes dummy gate stacks with different gate lengths (e.g., Lg1, Lg2), upon completion of the performing of the selective isotropic etching process for forming the inner spacer recesses, the part of the middle portion 204M under the dummy gate stack 214B may not be fully removed, leaving a residue (e.g., SiGe) disposed vertically between the channel layer 208U3 and the channel layer 208L1. If left untreated, the residue may provide a current path between the gate structure of the bottom GAA transistor and the gate structure of the top GAA transistor, leading to performance issue and reliability issue. In this disclosure, to eliminate current path caused by the residue, instead of forming a sacrificial middle portion 204M and then replacing it with an isolation layer, the superlattice structure 204 of the present embodiment includes a dielectric layer 207 providing isolation between the top portion 204T and the bottom portion 204B and thus providing the isolation between the gate structure of the bottom GAA transistor and the gate structure of the top GAA transistor.

After the formation of the inner spacer recesses, an inner spacer material layer is deposited over the intermediate structure 200, including in the inner spacer recesses. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess portions of the inner spacer material layer over the dummy gate stack 214, the gate spacer 222, and sidewalls of the channel layers 208, thereby forming the inner spacer features 226 as shown in FIG. 7. In the present embodiments, the inner spacer features 226 includes inner spacer features 226a and 226b disposed over the dielectric layer 207 and inner spacer features 226c, 226d, and 226e disposed under the dielectric layer 207. For embodiments in which the dielectric layer 207 is slightly etched during the formation of the inner spacer recesses, the intermediate structure 200 may also include inner spacer features disposed laterally adjacent to and in direct contact with the partially recessed dielectric layer 207. In some embodiments, the etch back process at block 110 may be a dry etch process that includes use of an oxygen-containing gas, hydrogen, nitrogen, a fluorine-containing gas (e.g., NF₃, CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof. In an embodiment, the dry etch process etches the inner spacer material layer without substantially etching the dielectric layer 207.

Still referring to FIGS. 2 and 7, method 100 includes a block 112 where bottom source/drain features 230 are formed in the trenches 224. In some embodiments, before the deposition of the bottom source/drain features 230, a blocking layer (not shown) may be deposited over the intermediate structure 200 to cover sidewalls of the top portion 204T of the superlattice structure 204. The blocking layer may also cover sidewalls of the dielectric layer 207 and the channel layer 208L1. The blocking layer may include dielectric materials. After the formation of the blocking layer, the bottom source/drain features 230 may be formed using an epitaxial process, such as VPE, UHV-CVD, MBE, and/or other suitable processes. The epitaxial growth process may use gaseous and/or liquid precursors, which interact with the composition of the substrate 202 as well as the channel layers 208 not covered by the blocking layer. In the present embodiments, the epitaxial growth of bottom source/drain features 230 may take place from both the top surface of the substrate 202 and the exposed sidewalls of the bottom channel layers 208L2 and 208L3. The blocking layer, due to its dielectric composition, blocks formation of the bottom source/drain features 230 on sidewalls of the channel layers 208U1-208U3 and 208L1. As illustrated in FIG. 7, the bottom source/drain features 230 are in physical contact with (or adjoining) the channel layers 208L2 and 208L3. Depending on the design, the bottom source/drain features 230 may be n-type or p-type. In the depicted embodiments, the bottom source/drain features 230 are p-type source/drain features and may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process.

Still referring to FIGS. 2 and 7, method 100 includes a block 114 where a bottom contact etch stop layer (CESL) 232 and a bottom interlayer dielectric (ILD) layer 234 are deposited over the bottom source/drain features 230. The bottom CESL 232 may include silicon nitride, silicon oxynitride, and/or other materials and may be formed by CVD, ALD, plasma-enhanced chemical vapor deposition (PECVD) process and/or other suitable deposition or oxidation processes. In an embodiment, the bottom CESL 232 includes silicon nitride. In some embodiments, the bottom CESL 232 is first conformally deposited on the intermediate structure 200 and the bottom ILD layer 234 is deposited over the bottom CESL 232 by spin-on coating, flowable CVD (FCVD), CVD, or other suitable deposition technique. The bottom ILD layer 234 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. After deposition, the bottom CESL 232 and the bottom ILD layer 234 are etched back. As shown in FIG. 7, the bottom CESL 232 and the bottom ILD layer 234 are etched back to exposed sidewalls of the channel layers 208U1 and 208U2. In embodiments presented by FIG. 7, after being etched back, the bottom CESL 232 is in direct contact with the inner spacer features 226b-226c, the channel layers 208U3 and 208L1, and the dielectric layer 207. The blocking layer may be removed during or after the etch back of the bottom CESL 232 and the bottom ILD layer 234.

Still referring to FIGS. 2 and 7, method 100 includes a block 116 where top source/drain features 248 are formed over the bottom CESL 232 and the bottom ILD layer 234. The top source/drain features 248 may be formed using an epitaxial process, such as VPE, UHV-CVD, MBE, and/or other suitable processes. The epitaxial growth process may use gaseous and/or liquid precursors, which interact with composition of the channel layers (e.g., channel layers 208U1 and 208U2) of the top portion 204T of the superlattice structure 204. The epitaxial growth of top source/drain features 248 may take place from the exposed sidewalls of the top channel layers 208U1 and 208U2. The deposited top source/drain features 248 are in physical contact with (or adjoining) the channel layers of the top portion 204T of the superlattice structure 204. Depending on the design, the top source/drain features 248 may be n-type or p-type. In the depicted embodiments, the top source/drain features 248 are n-type source/drain features and may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process.

Still referring to FIGS. 2 and 7, method 100 includes a block 118 where a top CESL 250 and a top ILD layer 252 are deposited over the top source/drain features 248. The top CESL 250 may include silicon nitride, silicon oxynitride, and/or other materials known in the art and may be formed by CVD, ALD, plasma-enhanced chemical vapor deposition (PECVD) process and/or other suitable deposition or oxidation processes. In some embodiments, the top CESL 250 is first conformally deposited on the intermediate structure 200 and the top ILD layer 252 is then deposited over the top CESL 250 by spin-on coating, FCVD, CVD, or other suitable deposition technique. The top ILD layer 252 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the top ILD layer 252, the intermediate structure 200 may be annealed to improve integrity of the top ILD layer 252. To remove excess materials and to expose top surfaces of dummy gate electrode layers 218 of dummy gate stacks 214, a planarization process, such a chemical mechanical polishing (CMP) process may be performed.

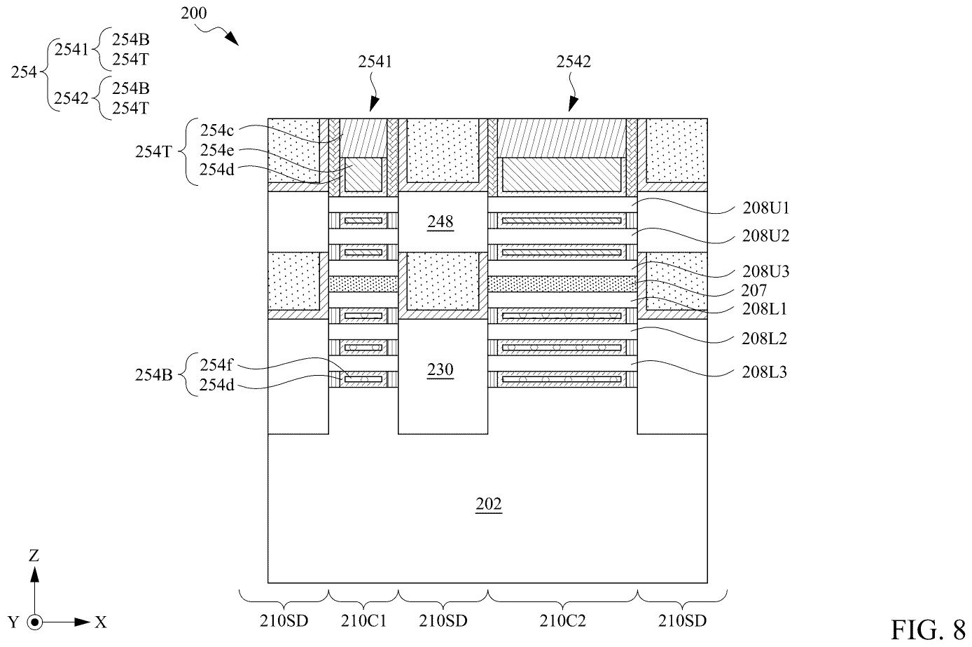

Referring to FIGS. 2 and 8, method 100 includes a block 120 where each of the dummy gate stacks 214 is replaced with a gate structure 254. Operations at block 120 may include removal of the dummy gate stacks 214, release of the channel layers 208 as channel members (including top channel layers 208U1 and 208U2, and bottom channel layers 208L2 and 208L3) and nanostructures (including the channel layers 208U3 and 208L1) and formation of gate structures 254 to wrap around the channel members. The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. After the removal of the dummy gate stacks 214, sidewalls of the channel layers 208 and sacrificial layers 206 in the channel regions 210C are exposed. Thereafter, the sacrificial layers 206 in the channel regions 210C are selectively removed to release the channel layers 208 as the channel members (including top channel layers 208U1 and 208U2, and bottom channel layers 208L2 and 2080L3) and nanostructures (including the channel layers 208U3 and 208L1). The selective removal of the sacrificial layers 206 may be implemented by a selective dry etch, a selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH. In embodiments represented by FIG. 7, the top channel layers 208U1 and 208U2 are in direct contact with the top source/drain features 248; the bottom channel layers 208L2 and 208L3 are in direct contact with the bottom source/drain features 230; and the channel layers 208U3 and 208L1 and the dielectric layer 207 are in direct contact with the bottom CESL 232.

After the selective removal of the sacrificial layers 206, the gate structures 254 are deposited to wrap around each of the top channel layers 208U1 and 208U2 and bottom channel layers 208L2 and 208L3, thereby forming bottom multi-gate transistors (e.g., 10L in FIG. 1) and top multi-gate transistors (e.g., 10U in FIG. 1) disposed over the bottom multi-gate transistors. In the depicted embodiments, both the bottom multi-gate transistor and the top multi-gate transistor are GAA transistors. In some embodiments, the gate structure 254 may be a common gate structure to wrap around the bottom channel members and the top channel members. In some other embodiments depicted in the drawings, each gate structure 254 includes a bottom gate portion 254B to wrap around the bottom channel layers 208L2 and 208L3 and a top gate portion 254T to wrap around the top channel layers 208U1 and 208U2. The bottom gate portion 254B and the top gate portion 254T have different work function layers. When the gate structure 254 includes a bottom gate portion 254B and a top gate portion 254T, the two gate portions may be electrically isolated from each other by the dielectric layer 207. For example, the bottom gate portion 254B may include p-type work function layers and the top gate portion 254T may include n-type work function layers. While not explicitly shown in the figures, the gate structure 254 includes an interfacial layer to interface the channel members. Each gate structure 254 also includes a gate dielectric layer 254d over the interfacial layer, a work function layer 254e/254f (e.g., a p-type work function layer or an n-type work function layer). The gate dielectric layer 254d is deposited over the intermediate structure 200 using ALD, CVD, and/or other suitable methods. The gate dielectric layer 254d is formed of high-K dielectric materials. As used and described herein, high-K dielectric materials include dielectric materials having a high dielectric constant, for example, greater than that of thermal silicon oxide (~3.9). The gate dielectric layer 254d may include hafnium oxide. Alternatively, the gate dielectric layer 254d may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material.

After the deposition of the gate dielectric layer 254d, n-type work function layer 254e and the p-type work function layer 254f may be formed over the channel regions 210C. The p-type work function layer 254f and the n-type work function layer 254e may include a single layer or alternatively a multi-layer structure, such as various combinations of a metal layer with a selected work function to enhance the device performance (work function metal layer). By way of example, the p-type work function layer 254f may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The n-type work function layer 254e may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. The gate structure 254 may also include a metal fill to reduce contact resistance. In some instance, the metal fill includes tungsten (W). The gate structure 254 may also include a liner layer, a wetting layer, an adhesion layer, a metal alloy or a metal silicide. In the depicted embodiment, the top gate portion 254T also includes a dielectric capping layer 254c formed over the n-type work function layer 254e. The gate structures 254 has a first gate structure 2541 and a second gate structure 2542. It is noted that, the first gate structure 2541 that replaces the dummy gate stack 214A has the gate length Lg1, and the second gate structure 2542 that replaces the dummy gate stack 214B has the gate length Lg2 greater than the firs gate length Lg1.

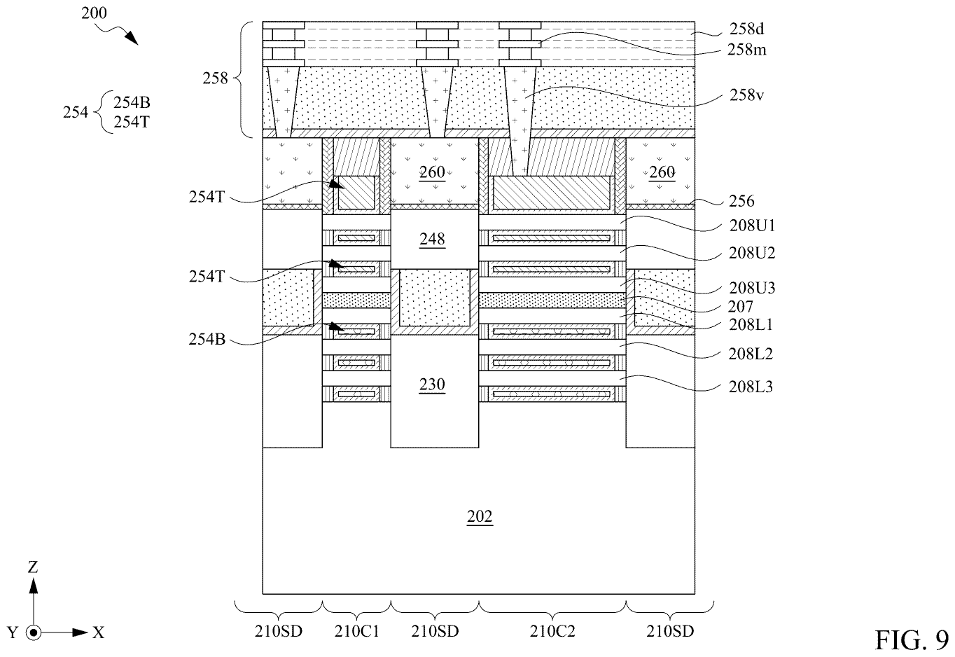

Referring to FIGS. 2 and 9, method 100 includes a block 122 where further processes are performed to complete the fabrication of the semiconductor device 200. Such further processes may include forming a silicide layer 256 over the top source/drain features 248 and forming a multi-layer interconnect (MLI) structure 258 over the intermediate structure 200. The MLI 258 may include various interconnect features, such as vias 258v and conductive lines 258m, disposed in dielectric layers 258d, such as etch-stop layers and ILD layers. In some embodiments, the vias are vertical interconnect features configured to interconnect device-level contacts, such as source/drain contacts 260 formed over the top source/drain features 248. Other processes may be further performed.

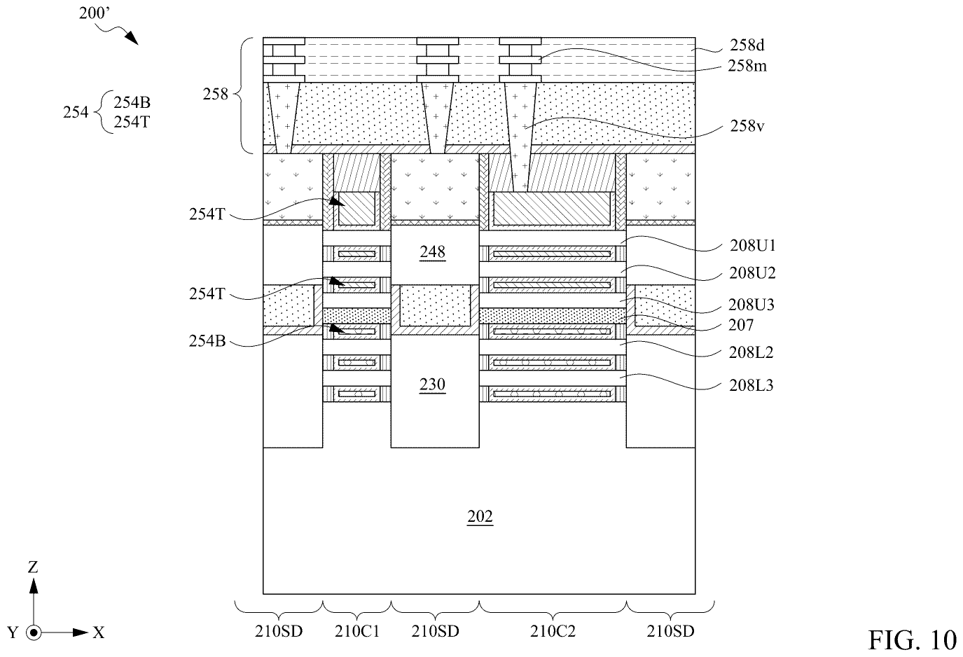

In the above embodiments represented by FIGS. 3-12, the semiconductor device 200 includes the dielectric layer 207 in direct contact with both the channel layer 208U3 and the channel layer 208L1. Unlike those existing technologies, since the middle portion 204M is formed during the formation of the superlattice structure 204 and is formed of the dielectric layer 207 that will not be replaced in subsequent processes, there is no need to form the channel layer 208U3 and/or the channel layer 208L1 in the superlattice structure 204. Each of FIGS. 10, 11, 12 depicts a fragmentary cross-sectional view of an alternative embodiment of the semiconductor device 200. For example, the semiconductor device 200′ represented by FIG. 10 is substantially similar to the semiconductor device 200 represented by FIG. 9, and one of the two differences between the semiconductor devices 200 and 200′ includes that, the semiconductor device 200′ does not include the channel layer 208L1. That is, the dielectric layer 207 is in direct contact with the bottom gate portion 254B and the inner spacer feature 226c. In this alternative embodiment, a distance between the dielectric layer 207 and the bottom gate portion 254B is less than a distance between the dielectric layer 207 and the top gate portion 254T. This embodiment can be achieved by omitting the epitaxial process for forming the channel layer 208L1 during the formation of the superlattice structure 204.

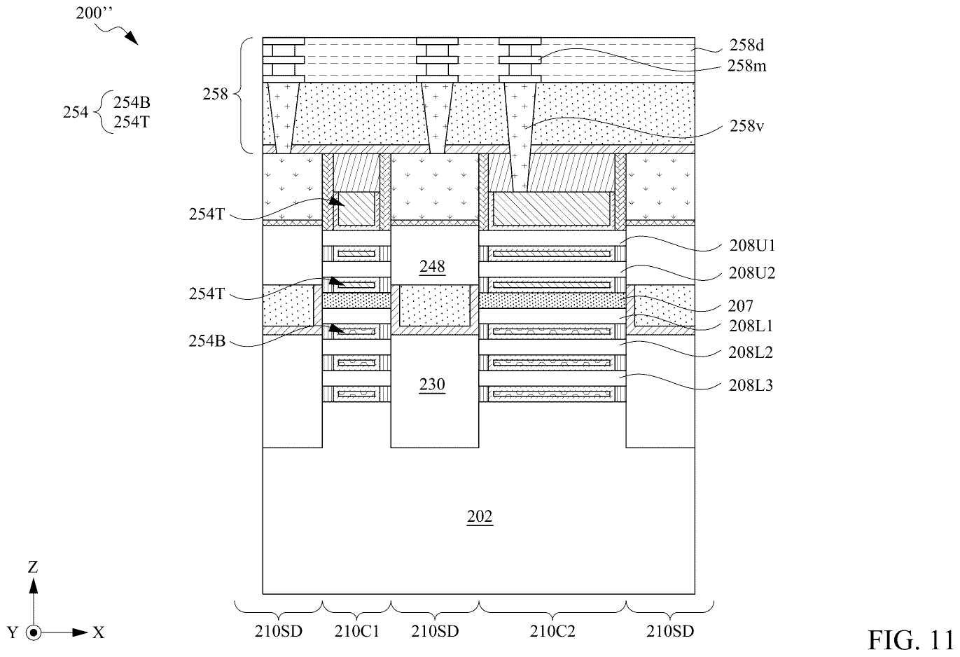

The semiconductor device 200″ represented by FIG. 11 is substantially similar to the semiconductor device 200 represented by FIG. 9, and one of the two differences between the semiconductor device 200 and the semiconductor device 200″ includes that, the semiconductor device 200″ does not include the channel layer 208U3. That is, the dielectric layer 207 is in direct contact with the top gate portion 254T and the inner spacer feature 226b. In this alternative embodiment, a distance between the dielectric layer 207 and the top gate portion 254T is less than a distance between the dielectric layer 207 and the bottom gate portion 254B. This embodiment can be achieved by omitting the epitaxial process for forming the channel layer 208U3 during the formation of the superlattice structure 204.

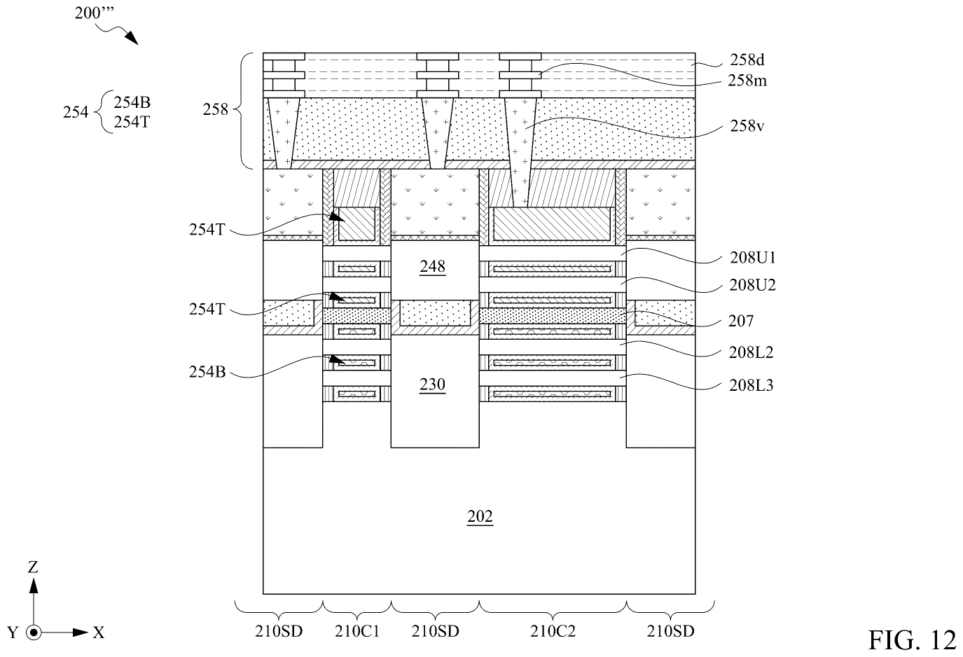

The semiconductor device 200′″ represented by FIG. 12 is substantially similar to the semiconductor device 200 represented by FIG. 9, and one of the two differences between the semiconductor device 200 and the semiconductor device 200″ includes that, the semiconductor device 200″ does not include both of the channel layer 208U3 and the channel layer 208L1. That is, the dielectric layer 207 is in direct contact with the top gate portion 254T, the inner spacer feature 226b, the bottom gate portion 254B, and the inner spacer feature 226c. In this alternative embodiment, a distance between the dielectric layer 207 and the top gate portion 254T is equal to a distance between the dielectric layer 207 and the bottom gate portion 254B. This embodiment can be achieved by omitting the epitaxial process for forming the channel layer 208U3 and omitting the epitaxial process for forming the channel layer 208L1 during the formation of the superlattice structure 204.

FIG. 13 illustrates a flow chart of another method 300 for forming a semiconductor device 400 (e.g., GAA transistors), according to one or more aspects of the present disclosure. FIGS. 14-19 illustrate fragmentary cross-sectional views of the semiconductor device 400 during various fabrication stages in the method 300 of FIG. 13, according to one or more aspects of the present disclosure.

Referring now to FIGS. 13 and 14, method 300 includes a block 302 where a vertical stack 404 is formed over the substrate 202. In the depicted embodiment, the vertical stack 404 includes include a number of channel layers 408 interleaved by a number of sacrificial layers 406. Each of the channel layers 408 may be formed of a semiconductor material such as silicon (Si), germanium (Ge), silicon germanium (SiGe), and each of the sacrificial layers 406 may be formed of a dielectric material. In an embodiment, formation and composition of each of the sacrificial layers 406 are substantially the same as those of the dielectric layer 207. For example, each of the sacrificial layers 406 may be formed of crystalline metal oxide and formed by an ALD process. It is noted that the vertical stack 404 in FIG. 14 includes three (3) layers of the channel layers 408 interleaved by three (3) layers of sacrificial layers 406, which is for illustrative purposes only and not intended to be limiting beyond what is specifically recited in the claims.

Still referring to FIGS. 13 and 14, method 300 includes a block 304 where the vertical stack 404 and a top portion of the substrate 202 are patterned to form fin-shaped structures. After forming the vertical stack 404, the vertical stack 404 and a portion of the substrate 202 are patterned to form fin-shaped structures 410. The fin-shaped structure 410 may be patterned in a way similar to that of the fin-shaped structures 210, and repeated description is omitted for reason of simplicity. As shown in FIG. 14, the fin-shaped structure 410 extends vertically along the Z direction from the substrate 202 and extends lengthwise along the X direction. After forming the fin-shaped structures 410, an isolation feature (not shown) is formed around the fin-shaped structures 410to separate two adjacent fin-shaped structures 410. The isolation feature is similar to the isolation feature 212, and repeated description is omitted for reason of simplicity.

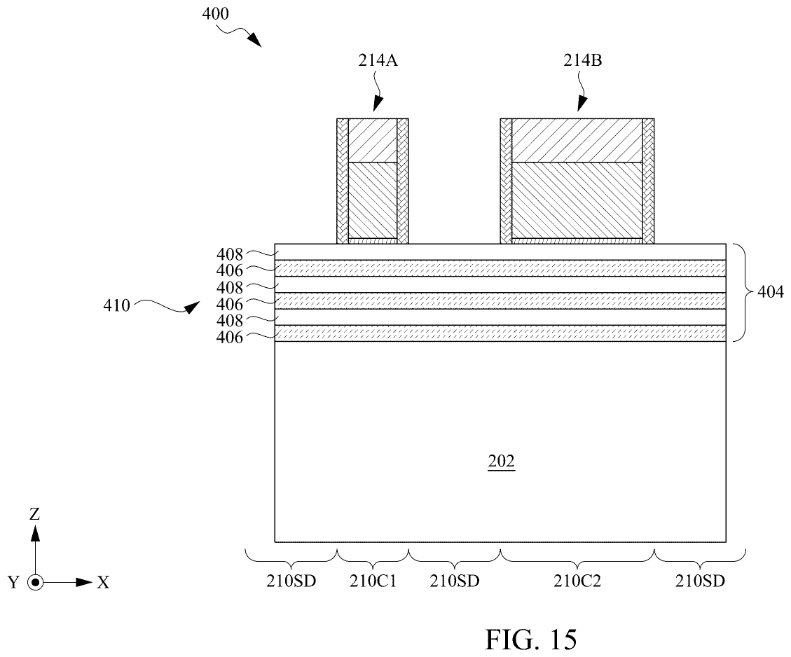

Referring now to FIGS. 13 and 15, method 300 includes a block 306 where dummy gate stacks 214 are formed over the fin-shaped structures 410, including directly over the channel regions 210C of the fin-shaped structures 410. The formation and composition of the dummy gate stacks 214A and 214B have been described above, and repeated description is omitted for reason of simplicity.

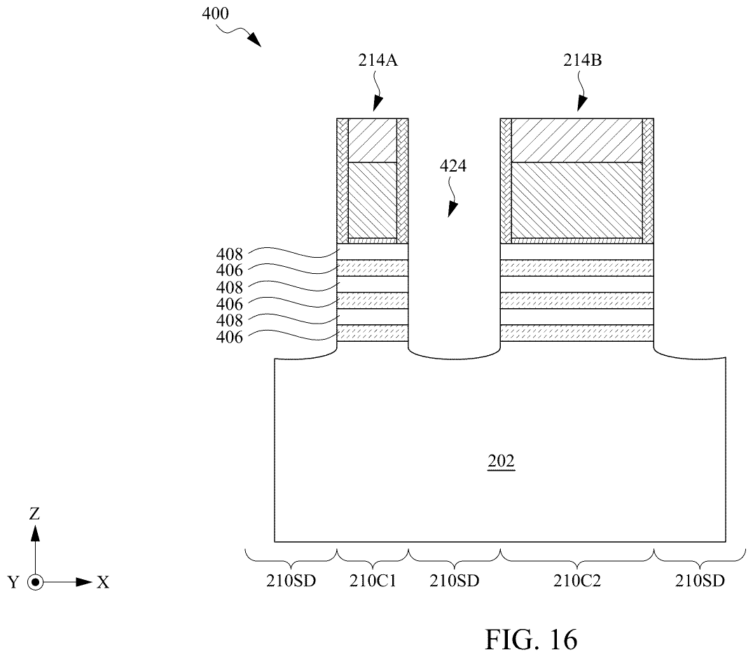

Referring now to FIGS. 13 and 16, method 300 includes a block 308 where trenches 424 are formed to extend through the fin-shaped structures 410. Operations at block 308 are similar to the operations at block 108, and one of the differences includes that, as shown in FIG. 16, sidewalls of the sacrificial layers 406 and the channel layers 408 in the channel regions 210C are exposed in the trenches 424.

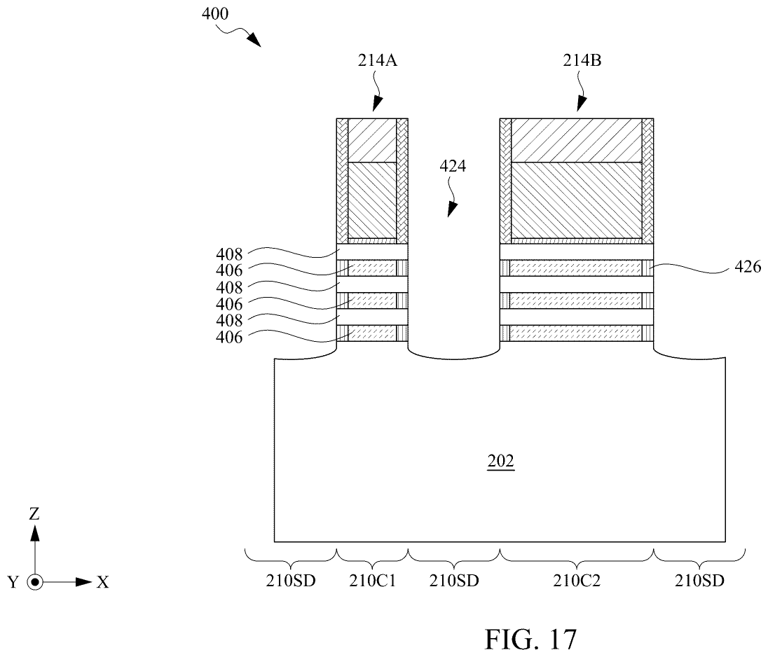

Referring now to FIGS. 13 and 17, method 300 includes a block 310 where inner spacer features 426 are formed. After the formation of the trenches 424, the sacrificial layers 406 exposed in the trenches 424 are selectively and partially recessed to form inner spacer recesses (now filled by inner spacer features 426), while the exposed channel layers 408 are not significantly etched. After the formation of the inner spacer recesses, an inner spacer material layer is deposited over the substrate 202, including in the inner spacer recesses. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excessive inner spacer material layer over sidewalls of the channel layers 408, thereby forming the inner spacer features 426 as shown in FIG. 17.

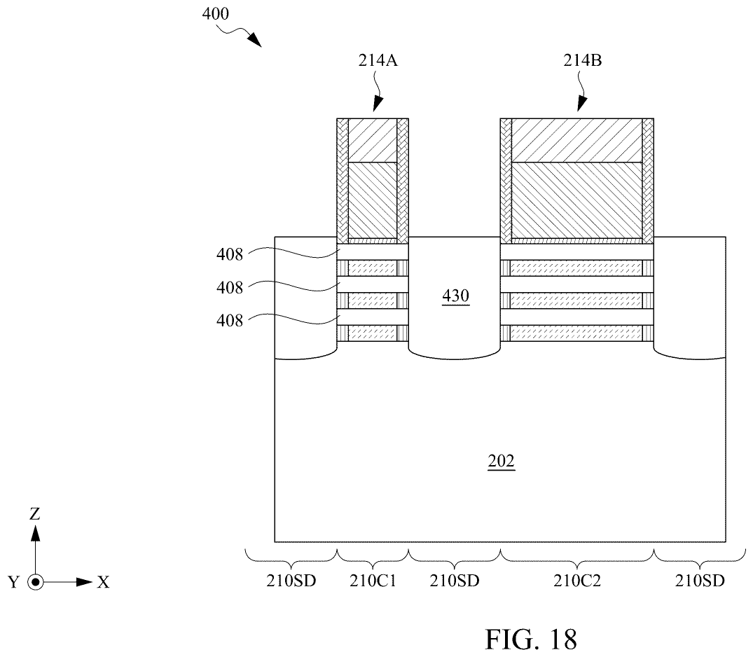

Referring now to FIGS. 13 and 18, method 300 includes a block 312 where source/drain features 430 are formed in the trenches 424. The source/drain features 430 are formed in and/or over source/drain regions and coupled to the channel layers 408 in the channel regions. The source/drain features 430 may be formed using an epitaxial process, such as VPE, UHV-CVD, MBE, and/or other suitable processes. Depending on the conductivity type of the to-be-formed transistor, the source/drain features 430 may be n-type source/drain features or p-type source/drain features. Exemplary n-type source/drain features may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Exemplary p-type source/drain features may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. The source/drain feature 430 may include one or more epitaxial layers, and dopant concentrations of the epitaxial layers may be same or different. In some embodiments, top surfaces of the source/drain features 430 are not coplanar with a top surface of the topmost channel layer 408 of the channel layers 408 and may include curved surfaces.

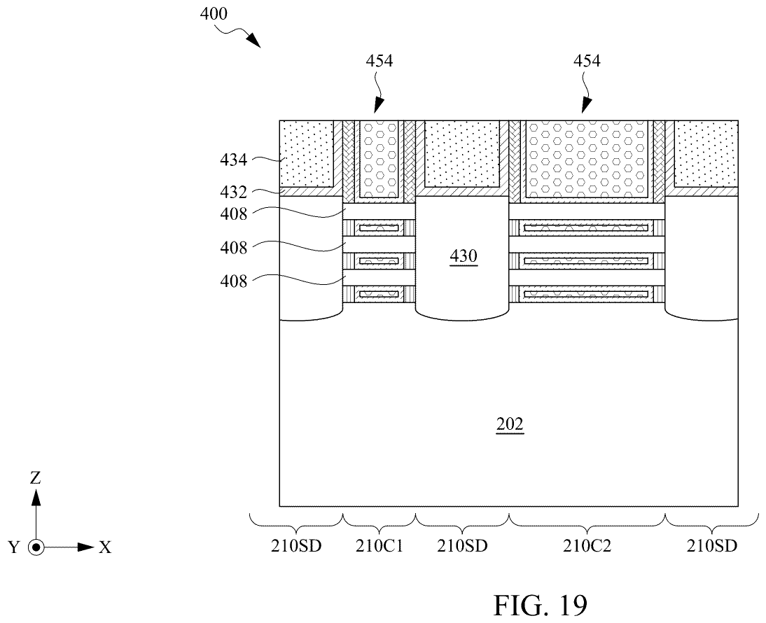

Referring now to FIGS. 13 and 19, method 300 includes a block 314 where a contact etch stop layer 432 and an interlayer dielectric (ILD) layer 434 are formed. The formation and composition of the contact etch stop layer 432 are similar to those of the bottom CESL 232, and the formation and composition of the ILD 434 are similar to those of the bottom ILD 243, and repeated description is omitted for reason of simplicity.

Still referring to FIGS. 13 and 19, method 300 includes a block 316 where the dummy gate stacks 214 and the sacrificial layers 406 are replaced with gate structures 454. A planarization process, such a chemical mechanical polishing (CMP) process may be performed to the intermediate structure 400 to remove excessive materials and expose top surfaces of the dummy gate electrode layer 218 in the dummy gate stacks 214. With the exposure of the dummy gate electrode layer 218, block 316 proceeds to removal of the dummy gate stacks 214. The removal of the dummy gate stacks 214 may include one or more etching process that are selective to the material in the dummy gate stacks 214. For example, the removal of the dummy gate stacks 214 may be performed using a selective wet etch, a selective dry etch, or a combination thereof. After the removal of the dummy gate stacks 214, the sacrificial layers 406 are selectively removed to release the channel layers 408 as channel members 408 in the channel regions 210C. The gate structures 454 are then formed to wrap around the channel members 408. The gate structure 454 includes an interfacial layer disposed on the channel members, a gate dielectric layer over the interfacial layer, and a gate electrode layer over the gate dielectric layer. In some embodiments, the gate dielectric layer is a high-k dielectric layer over the interfacial layer. The gate electrode layer is then deposited over the gate dielectric layer using ALD, PVD, CVD, e-beam evaporation, or other suitable methods. The gate electrode layer may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride, titanium aluminum, titanium aluminum nitride, tantalum nitride, tantalum aluminum, tantalum aluminum nitride, tantalum aluminum carbide, tantalum carbonitride, aluminum, tungsten, nickel, titanium, ruthenium, cobalt, platinum, tantalum carbide, tantalum silicon nitride, copper, other refractory metals, or other suitable metal materials or a combination thereof. Further, where the semiconductor device includes n-type transistors and p-type transistors, different gate electrode layers may be formed separately for n-type transistors and p-type transistors, which may include different work function metal layers (e.g., for providing different n-type and p-type work function metal layers).

Referring back to FIG. 13, method 300 includes a block 318 where further processes are performed. Such further performances may include forming an interconnect structure. The interconnect structure may include multiple intermetal dielectric (IMD) layers and multiple metal lines or contact vias in each of the IMD layers. In some instances, the IMD layers and the ILD layer may share similar composition. The metal lines and contact vias in each IMD layer may be formed of metal, such as aluminum, tungsten, ruthenium, or copper. In some embodiments, the metal lines and contact vias may be lined by a barrier layer to insulate the metal lines and contact vias from the IMD layers and to prevent electro-migration.

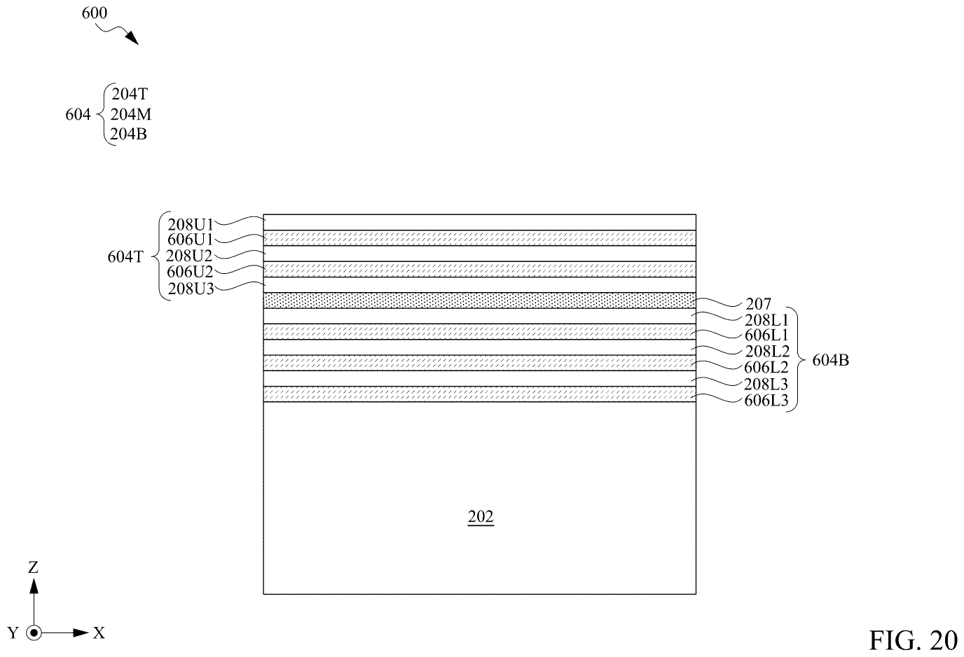

In the above embodiments described with reference to FIG. 1-12, each of the top portion 204T and the bottom portion 204B of the superlattice structure 204 includes a vertical stack of alternating channel layers 208 and sacrificial layers 206, and the sacrificial layers 206 are formed of a semiconductor material (e.g., SiGe). In another embodiment represented by FIGS. 20-24, the sacrificial layers may include a dielectric material. FIGS. 20, 21, 22, 23 illustrate fragmentary cross-sectional views of an alternative semiconductor device 600 during various fabrication stages in the method 100 of FIG. 2, according to various aspects of the present disclosure, according to one or more aspects of the present disclosure.

Referring now to FIGS. 20 and 2, method 100 includes block 102 where a superlattice structure 604 is formed over the substrate 202. The superlattice structure 604 is similar to the superlattice structure 204, and one of the differences between the superlattice structure 204 and the superlattice structure 604 includes that, sacrificial layers (e.g., sacrificial layers 606U1, 606U2) of the top portion 604T of the superlattice structure 604 and sacrificial layers (e.g., sacrificial layers 606L1, 606L2, 606L3) of the bottom portion 604B of the superlattice structure 604 are formed of a dielectric material. The sacrificial layers 606U1, 606U2, 606L1, 606L2, 606L3 may be separately or collectively referred to as the sacrificial layer(s) 606. In an embodiment, the sacrificial layer 606 may be formed of a crystalline metal oxide, such as beryllium oxide (BeO), aluminum oxide (Al₂O₃) or other suitable materials, and may be formed by atomic layer deposition (ALD) process, plasma-enhanced atomic layer deposition process (PEALD), or other suitable processes. A composition of the sacrificial layer 606 is different from a composition of the dielectric layer 207, thereby providing etch selectively between the sacrificial layer 606 and the dielectric layer 207 during subsequent fabrication process (e.g., operations at blocks 110 and 120).

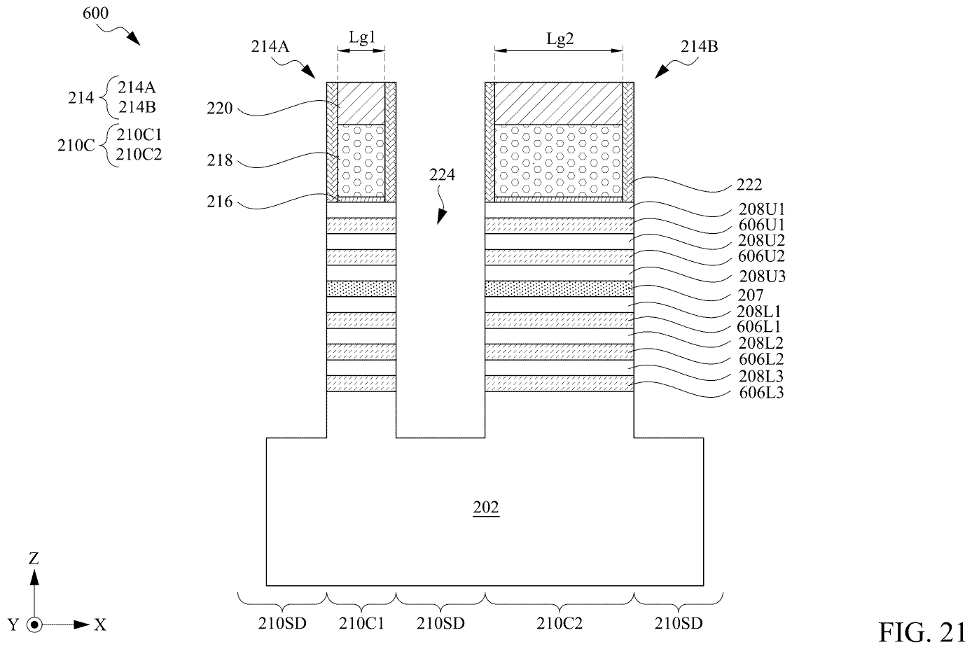

With reference to FIGS. 21 and 2, after forming the superlattice structure 604, operations at blocks 104-108 of method 100 are then performed. Operations at blocks 104-108 have been described above, and repeated description is omitted for reason of simplicity.

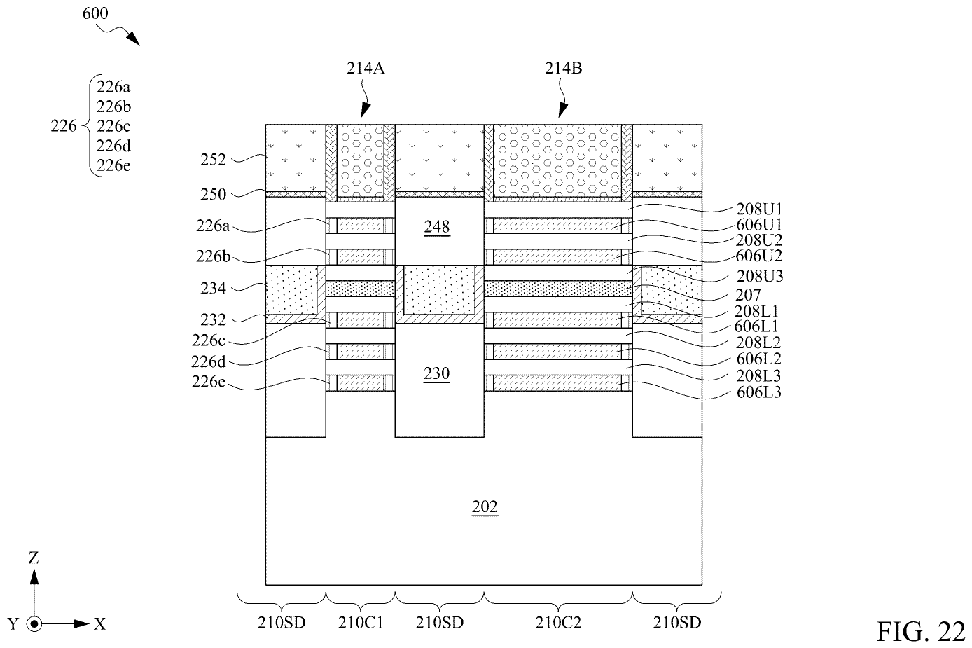

With reference to FIGS. 22 and 2, method 100 proceeds to block 110 where inner spacer features 226 are formed. In this embodiment, the sacrificial layers 606 exposed in the trenches 224 are selectively and partially recessed to form inner spacer recesses, and the exposed channel layers 208 and the dielectric layer 207 are substantially unetched. In an embodiment, etchant of the selective isotropic etching process etches the channel layers 208 at a first rate, etches the dielectric layer 207 at a second rate, and etches the sacrificial layers 606 at a third rate. The third rate is greater than the first rate and the second rate. Inner spacer features 226 are then formed, as described above with reference to FIG. 7.

Still referring to FIGS. 22 and 2, after forming the inner spacer features 226, operations at blocks 112-118 of method 100 are then performed. Operations at blocks 112-118 have been described above, and repeated description is omitted for reason of simplicity.

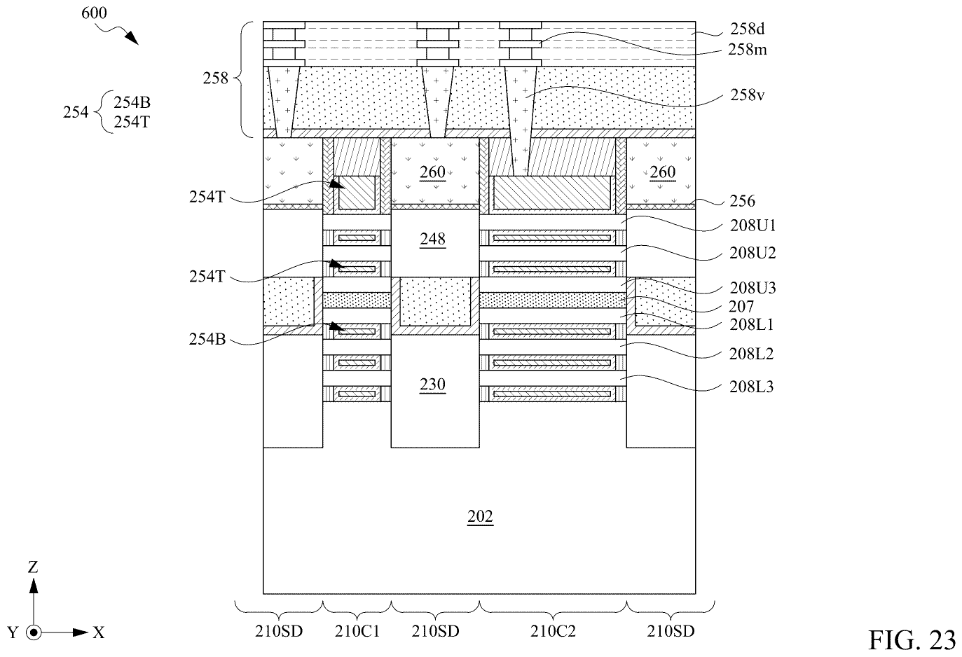

With reference to FIGS. 23 and 2, method 100 proceeds to block 120 where the dummy gate stacks 214 are replaced with the gate structures 254. Operations at block 120 may include removal of the dummy gate stacks 214, release of the channel layers 208 as channel members (including top channel layers 208U1 and 208U2, and bottom channel layers 208L2 and 208L3) and nanostructures (including the channel layers 208U3 and 208L1) and formation of gate structures 254 to wrap around the channel members. The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. After the removal of the dummy gate stacks 214, sidewalls of the channel layers 208 and sacrificial layers 606 in the channel regions 210C are exposed. Thereafter, the sacrificial layers 606 in the channel regions 210C are selectively removed to release the channel layers 208 as the channel members (including top channel layers 208U1 and 208U2, and bottom channel layers 208L2 and 2080L3) and nanostructures (including the channel layers 208U3 and 208L1). The selective removal of the sacrificial layers 606 may be implemented by a selective dry etch, a selective wet etch, or other selective etch processes. Details of the gate structures 254 have been described above, and repeated description is omitted for reason of simplicity. The alternative semiconductor device 200′, 200″, and 200′″ described above may also be formed in a way similar to that of the semiconductor device 600.

Although not intended to be limiting, one or more embodiments of the present disclosure provide many benefits to a semiconductor device and the formation thereof. For example, the present disclosure provides a superlattice structure including a dielectric layer disposed between a top portion of the superlattice structure for forming a top multi-gate device and a bottom portion of the superlattice structure for forming a bottom multi-gate device to prevent electrical short therebetween, thereby improving the overall reliability of the semiconductor device.

The present disclosure provides for many different embodiments. Semiconductor structures and methods of fabrication thereof are disclosed herein. In one exemplary aspect, the present disclosure is directed to a method. The method includes forming a superlattice structure over a substrate, the superlattice structure comprising an upper portion separated from a lower portion by an insulation layer, wherein the insulation layer comprises a crystalline metal oxide, patterning the superlattice structure to form a fin protruding from the substrate, forming a dummy gate stack over a first portion of the fin, recessing a second portion of the fin not covered by the dummy gate stack to form a source/drain trench, forming a first source/drain feature in the source/drain trench and coupled to the lower portion of the superlattice structure, forming a second source/drain feature in the source/drain trench and coupled to the upper portion of the superlattice structure, and replacing the dummy gate stack by a gate structure.

In some embodiments, the crystalline metal oxide may include beryllium oxide (BeO) or aluminum oxide (Al₂O₃). In some embodiments, the method may also include, after forming the first source/drain feature, forming a contact etch stop layer (CESL) and an interlayer dielectric (ILD) layer over the first source/drain feature. The first source/drain feature and the second source/drain feature are separated by the CESL and the ILD layer. In some embodiments, the lower portion of the superlattice structure may include a first plurality of channel layers interleaved by a first plurality of sacrificial layers, and the upper portion of the superlattice structure may include a second plurality of channel layers interleaved by a second plurality of sacrificial layers, and the method may also include, after the recessing of the second portion of the fin, performing an etching process to selectively recess the first plurality of sacrificial layers and the second plurality of sacrificial layers to form a first plurality of inner spacer recesses and a second plurality of inner spacer recesses, respectively, and forming a first plurality of inner spacer features in the first plurality of inner spacer recesses and a second plurality of inner spacer features in the second plurality of inner spacer recesses. In some embodiments, the etching process etches the first plurality of sacrificial layers and the second plurality of sacrificial layers at a first rate and etches the insulation layer at a second rate less than the first rate. In some embodiments, the replacing of the dummy gate stack by the gate structure may include selectively removing the dummy gate stack, selectively removing the first plurality of sacrificial layers and the second plurality of sacrificial layers, and forming the gate structure over the substrate, wherein the gate structure may include a first portion wrapping around the first plurality of channel layers and a second portion wrapping around the second plurality of channel layers, the first portion of the gate structure and the second portion of the gate structure are separated by the insulation layer. In some embodiments, the insulation layer is in direct contact with the first portion of the gate structure and the second portion of the gate structure. In some embodiments, a thickness of the insulation layer is in a range between about 5 nm and about 15 nm.

In another exemplary aspect, the present disclosure is directed to a method. The method includes forming a first vertical stack of alternating channel layers and sacrificial layers over a substrate, depositing a dielectric layer on the first vertical stack, forming a second vertical stack of alternating channel layers and sacrificial layers on the dielectric layer, patterning the second vertical stack, the dielectric layer, and the first vertical stack, thereby forming a fin-like structure over the substrate, forming a trench extending through the fin-like structure, performing a first etching process to selectively recess the sacrificial layers of the first vertical stack and the sacrificial layers of the second vertical stack, wherein etchant of the first etching process etches the sacrificial layers at a first rate and etches the dielectric layer at a second rate less than the first rate, performing a second etching process to selectively remove remaining portions of the sacrificial layers of the first vertical stack and remaining portions of the sacrificial layers of the second vertical stack, thereby forming first gate openings and second gate openings, respectively, and forming a first gate structure in the first gate openings and a second gate structure in the second gate openings.

In some embodiments, the depositing of the dielectric layer may include performing an atomic layer deposition (ALD) process, and the dielectric layer may include crystalline metal oxide. In some embodiments, the method may also include forming a first source/drain feature in the trench and coupled to channel layers of the first vertical stack, forming an isolation structure on the first source/drain feature, and forming a second source/drain feature in the trench and coupled to the channel layers of the second vertical stack. In some embodiments, the performing of the first etching process forms inner spacer recesses, and the method may also include forming inner spacer features in the inner spacer recesses, the inner spacer features and the dielectric layer have different compositions. In some embodiments, a topmost layer of the first vertical stack may include silicon germanium. In some embodiments, a bottommost layer of the second vertical stack may include silicon germanium. In some embodiments, the method may also include forming a first dummy gate stack and a second dummy gate stack over the fin-like structure, the first dummy gate stack and the second dummy gate stack have different gate lengths, wherein the trench is disposed between the first dummy gate stack and the second dummy gate stack, and before the performing of the second etching process, selectively removing the first dummy gate stack and the second dummy gate stack.

In yet another exemplary aspect, the present disclosure is directed to a semiconductor device. The semiconductor device includes a substrate, a lower source/drain feature disposed over the substrate, a first plurality of nanostructures coupled to the lower source/drain feature, a first gate structure wrapping around each of the first plurality of nanostructures, an upper source/drain feature over the lower source/drain feature, a second plurality of nanostructures coupled to the upper source/drain feature, a second gate structure wrapping around each of the second plurality of nanostructures, and a dielectric layer providing isolation between the first gate structure and the second gate structure, wherein the dielectric layer may include crystalline metal oxide.

In some embodiments, the semiconductor device may also include a contact etch stop layer (CESL) and an interlayer dielectric (ILD) layer disposed between the lower source/drain feature and the upper source/drain feature. In some embodiments, the semiconductor device may also include inner spacers disposed between the first gate structure and the lower source/drain feature and between the second gate structure and the upper source/drain feature, and the inner spacers and the dielectric layer have different compositions. In some embodiments, a thickness of the dielectric layer is in a range between about 5 nm and about 15 nm. In some embodiments, the dielectric layer is in direct contact with the first gate structure and the second gate structure.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a superlattice structure over a substrate, the superlattice structure comprising an upper portion separated from a lower portion by an insulation layer, wherein the insulation layer comprises a crystalline metal oxide;
patterning the superlattice structure to form a fin protruding from the substrate;
forming a dummy gate stack over a first portion of the fin;
recessing a second portion of the fin not covered by the dummy gate stack to form a source/drain trench;
forming a first source/drain feature in the source/drain trench and coupled to the lower portion of the superlattice structure;
forming a second source/drain feature in the source/drain trench and coupled to the upper portion of the superlattice structure; and
replacing the dummy gate stack by a gate structure.

2. The method of claim 1, wherein the crystalline metal oxide comprises beryllium oxide (BeO) or aluminum oxide (Al₂O₃).

3. The method of claim 1, further comprising:
after forming the first source/drain feature, forming a contact etch stop layer (CESL) and an interlayer dielectric (ILD) layer over the first source/drain feature,
wherein the first source/drain feature and the second source/drain feature are separated by the CESL and the ILD layer.

4. The method of claim 1, wherein the lower portion of the superlattice structure comprises a first plurality of channel layers interleaved by a first plurality of sacrificial layers, and the upper portion of the superlattice structure comprises a second plurality of channel layers interleaved by a second plurality of sacrificial layers, and the method further comprises:
after the recessing of the second portion of the fin, performing an etching process to selectively recess the first plurality of sacrificial layers and the second plurality of sacrificial layers to form a first plurality of inner spacer recesses and a second plurality of inner spacer recesses, respectively; and
forming a first plurality of inner spacer features in the first plurality of inner spacer recesses and a second plurality of inner spacer features in the second plurality of inner spacer recesses.

5. The method of claim 4, wherein the etching process etches the first plurality of sacrificial layers and the second plurality of sacrificial layers at a first rate and etches the insulation layer at a second rate less than the first rate.

6. The method of claim 4, wherein the replacing of the dummy gate stack by the gate structure comprises:
selectively removing the dummy gate stack;
selectively removing the first plurality of sacrificial layers and the second plurality of sacrificial layers; and
forming the gate structure over the substrate, wherein the gate structure comprises a first portion wrapping around the first plurality of channel layers and a second portion wrapping around the second plurality of channel layers, the first portion of the gate structure and the second portion of the gate structure are separated by the insulation layer.

7. The method of claim 4, wherein the insulation layer is in direct contact with the first portion of the gate structure and the second portion of the gate structure.

8. The method of claim 1, wherein a thickness of the insulation layer is in a range between about 5 nm and about 15 nm.

9. A method, comprising:
forming a first vertical stack of alternating channel layers and sacrificial layers over a substrate;
depositing a dielectric layer on the first vertical stack;
forming a second vertical stack of alternating channel layers and sacrificial layers on the dielectric layer;
patterning the second vertical stack, the dielectric layer, and the first vertical stack, thereby forming a fin-like structure over the substrate;
forming a trench extending through the fin-like structure;
performing a first etching process to selectively recess the sacrificial layers of the first vertical stack and the sacrificial layers of the second vertical stack, wherein etchant of the first etching process etches the sacrificial layers at a first rate and etches the dielectric layer at a second rate less than the first rate;
performing a second etching process to selectively remove remaining portions of the sacrificial layers of the first vertical stack and remaining portions of the sacrificial layers of the second vertical stack, thereby forming first gate openings and second gate openings, respectively; and
forming a first gate structure in the first gate openings and a second gate structure in the second gate openings.

10. The method of claim 9, wherein the depositing of the dielectric layer comprises performing an atomic layer deposition (ALD) process, and the dielectric layer comprises crystalline metal oxide.

11. The method of claim 9, further comprising:
forming a first source/drain feature in the trench and coupled to channel layers of the first vertical stack;
forming an isolation structure on the first source/drain feature; and
forming a second source/drain feature in the trench and coupled to the channel layers of the second vertical stack.

12. The method of claim 9, wherein the performing of the first etching process forms inner spacer recesses, and the method further comprises forming inner spacer features in the inner spacer recesses, wherein the inner spacer features and the dielectric layer have different compositions.

13. The method of claim 9, wherein a topmost layer of the first vertical stack comprises silicon germanium.

14. The method of claim 9, wherein a bottommost layer of the second vertical stack comprises silicon germanium.

15. The method of claim 9, further comprising:
forming a first dummy gate stack and a second dummy gate stack over the fin-like structure, the first dummy gate stack and the second dummy gate stack have different gate lengths, wherein the trench is disposed between the first dummy gate stack and the second dummy gate stack; and
before the performing of the second etching process, selectively removing the first dummy gate stack and the second dummy gate stack.

16. A semiconductor device, comprising:
a substrate;
a lower source/drain feature disposed over the substrate;
a first plurality of nanostructures coupled to the lower source/drain feature;
a first gate structure wrapping around each of the first plurality of nanostructures;
an upper source/drain feature over the lower source/drain feature;
a second plurality of nanostructures coupled to the upper source/drain feature;
a second gate structure wrapping around each of the second plurality of nanostructures; and
a dielectric layer providing isolation between the first gate structure and the second gate structure, wherein the dielectric layer comprises crystalline metal oxide.

17. The semiconductor device of claim 16, further comprising:
a contact etch stop layer (CESL) and an interlayer dielectric (ILD) layer disposed between the lower source/drain feature and the upper source/drain feature.

18. The semiconductor device of claim 16, further comprising:
inner spacers disposed between the first gate structure and the lower source/drain feature and between the second gate structure and the upper source/drain feature, wherein the inner spacers and the dielectric layer have different compositions.

19. The semiconductor device of claim 16, wherein a thickness of the dielectric layer is in a range between about 5 nm and about 15 nm.

20. The semiconductor device of claim 16, wherein the dielectric layer is in direct contact with the first gate structure and the second gate structure.
